(19) United States
(12) Patent Application Publication
(10) Pub. No.: US 2009/0159993 A1
(43) Pub. Date: Jun. 25, 2009

(54) SEMICONDUCTOR DEVICE AND METHOD FOR FABRICATING THE SAME

(76) Inventor: Dae-Ho Jeong, Geumcheon-gu (KR)

Correspondence Address: SHERR & VAUGHN, PLLC, 620 HERNDON PARKWAY, SUITE 200, HERNDON, VA, 20170, US

(21) Appl. No.: 12/334,506

(22) Filed: Dec. 14, 2008

(30) Foreign Application Priority Data
Dec. 21, 2007 (KR) 10-2007-0134859

(51) Int. Cl. H01L 29/78; H01L 21/3205

(52) U.S. Cl. 257/412; 438/595; 257/E29.255; 257/E21.243; 257/E21.295

(57) ABSTRACT

A semiconductor device and/or a method for manufacturing a semiconductor device. A method may include at least one of the following: Forming a first oxide layer on a silicon substrate. Depositing a polysilicon layer on the first oxide layer. Forming a pattern on the polysilicon layer and the first oxide layer to expose a portion of the silicon substrate forming a polysilicon layer pattern and a first oxide layer pattern. Forming a second oxide layer on the entire surface of the silicon substrate. Forming a pattern on the second oxide layer to expose a portion of the silicon substrate. Growing a silicon on the exposed silicon substrate to form a silicon epitaxial layer. Removing the second oxide layer formed on the polysilicon layer pattern.

The present application claims priority under 35 U.S.C. 119 to Korean Patent Application No. 10-2007-0134859 (filed on Dec. 21, 2007), which is hereby incorporated by reference in its entirety.

### BACKGROUND

A trench metal-oxide-semiconductor field-effect transistor (MOSFET) is a transistor in which a channel is vertically formed and a gate extends from a source and a drain and is provided in the form of a trench between the source and the drain. The trench has an outline formed of a thin dielectric such as an oxide layer in a dug groove of a semiconductor substrate. The trench is filled with a conductor such as polysilicon to form a trench gate structure. A source region is formed by implanting high concentration ions along both sides of the trench. The trench may be filled with polysilicon and a polysilicon layer may be deposited on the entire surface of the semiconductor substrate. In general, the trench is formed to a depth of about 1.5 μm to about 2.0 μm and the polysilicon layer is deposited to a thickness of about 1.2 μm.

A poly etch-back process may then be performed to remove the polysilicon layer formed on the semiconductor substrate. The poly etch-back process may be performed using SF₆ or HBr. However, by-products or particles generated during the poly etch-back process may cause damage to the polysilicon layer formed in the trench, thus degrading the characteristics of the semiconductor device.

### SUMMARY

Embodiments relate to a semiconductor device with a simplified process and a method for fabricating the same.

Embodiment relate to a semiconductor device that may include at least one of the following: a first oxide layer pattern formed on a silicon substrate and a polysilicon layer pattern formed on and/or over the first oxide layer pattern. A silicon epitaxial layer may be formed on and/or over the silicon substrate at both sides of the polysilicon layer pattern and the first oxide layer pattern. A second oxide layer pattern may be formed between the polysilicon layer pattern and the silicon epitaxial layer. A source/drain region may be formed in the silicon epitaxial layer.

Embodiment relate to a fabricating method for a semiconductor device that may include at least one of the following: forming a first oxide layer on and/or over a silicon substrate and depositing a polysilicon layer on and/or over the first oxide layer. The polysilicon layer and the first oxide layer may be patterned to expose a portion of the silicon substrate, thereby forming a polysilicon layer pattern and a first oxide layer pattern. A second oxide layer may be formed on the entire surface of the silicon substrate. The second oxide layer may be patterned to expose a portion of the silicon substrate. Silicon may be grown on and/or over the exposed silicon substrate to form a silicon epitaxial layer. The second oxide layer formed on and/or over the polysilicon layer pattern may be removed.

Embodiments relate to a method that may include at least one of the following: forming a first oxide layer over a silicon substrate; and then forming a polysilicon layer over the first oxide layer; and then forming a polysilicon layer pattern and a first oxide layer pattern by etching the polysilicon layer and the first oxide layer to expose a portion of the silicon substrate; and then forming a second oxide layer over the entire surface of the silicon substrate including the uppermost surface of the polysilicon layer pattern; and then forming a second oxide layer pattern by etching the second oxide layer to expose a portion of the silicon substrate; and then forming a silicon epitaxial layer by growing a silicon over the exposed silicon substrate; and then removing a portion of the second oxide layer formed over the uppermost surface of the polysilicon layer pattern.

Embodiments may simplify the process for forming a transistor with a trench-type gate on a semiconductor substrate in a semiconductor device maximizing the production yield. Embodiments may minimize damage to a gate electrode in a semiconductor device, thereby minimizing the performance degradation of the semiconductor device.

### DRAWINGS

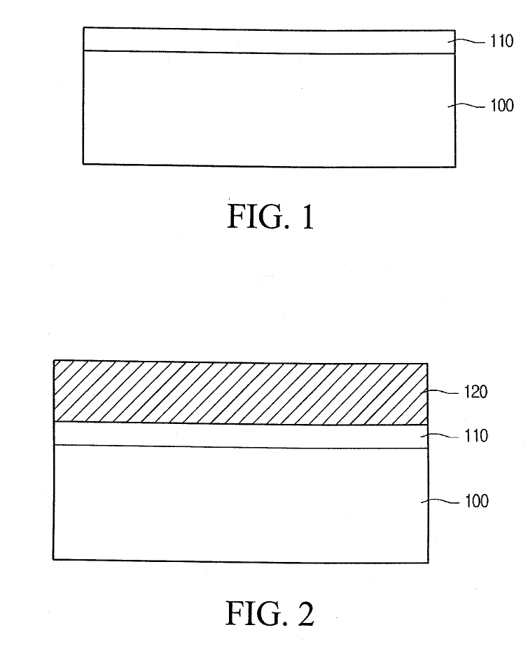

Example FIGS. 1 to 7 are cross-sectional views illustrating a method for fabricating a semiconductor device in accordance with embodiments.

### DESCRIPTION

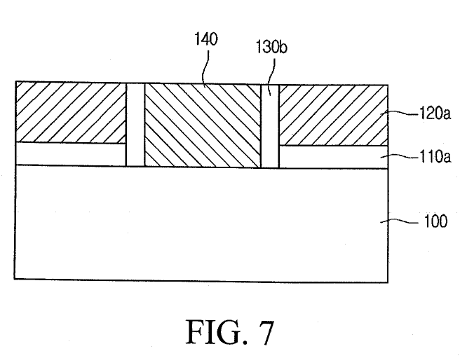

Hereinafter, a semiconductor device and a fabricating method thereof according to embodiments will be described in detail. Example FIG. 1 through example FIG. 7 illustrate cross-sectional views of according to embodiments.

As illustrated in example FIG. 1, a method for fabricating a semiconductor device in accordance with embodiments may include a first oxide layer 110 serving as a sub substrate may be formed on and/or over a silicon (Si) substrate 100. The first oxide layer 110 may be formed using a thermal oxidation process or a chemical vapor deposition (CVD) process. The first oxide layer 110 may be formed using a thermal oxidation process at a temperature of about 900° C. to about 1000° C. under an oxygen atmosphere. The first oxide layer 110 may be formed to a thickness of about 200 Å to about 300 Å.

As shown in example FIG. 2, a doped polysilicon layer 120 may be formed on and/or over the first oxide layer 110. The doped polysilicon layer 120 may be deposited to a thickness of about 1.0 μm to about 1.5 μm. Using SiH₄ or PH₃, for example, the doped polysilicon layer 120 may be deposited at by a CVD process at a temperature of about 500° C. to about 600° C. A photoresist layer may be formed on and/or over the doped polysilicon layer 120. Next, the photoresist layer may be exposed and developed to remove the photoresist in a moat region, thereby forming a first photoresist pattern.

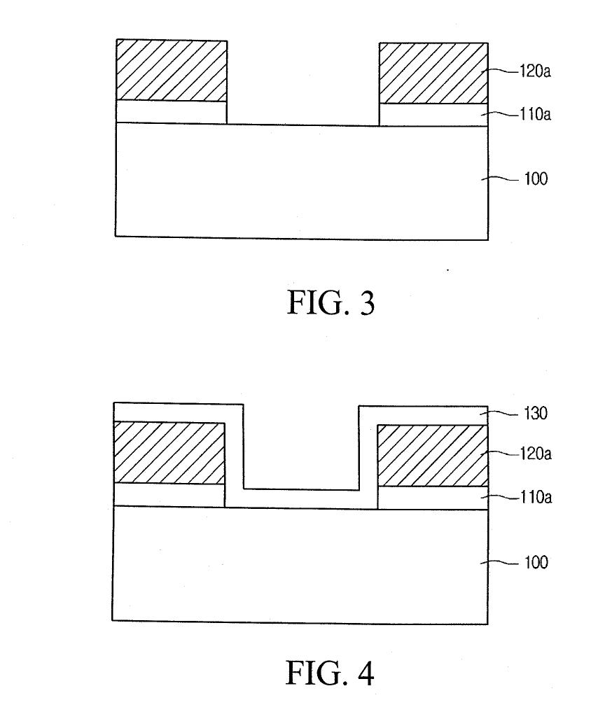

As shown in example FIG. 3, using the first photoresist pattern as an etch mask, the polysilicon layer 120 and the first oxide layer 110 may be etched to form a trench exposing a portion of the silicon substrate 100. The polysilicon layer 120 may be formed using a dry etching process such as a reactive ion etching (RIE) process. The dry etching process energizes and accelerates ions so that silicon atoms of the polysilicon layer 120 are physically or artificially collided with the accelerated ions, thereby removing the silicon atoms of the polysilicon layer 120. The exposed silicon substrate 100 corresponds to the moat region.

As illustrated in example FIG. 4, a second oxide layer 130 may be formed on and/or over a first oxide layer pattern 110a and a polysilicon layer pattern 120a that have been formed by the process of etching the polysilicon layer 120 including sidewalls of the trench. The second oxide layer 130 may be formed using a high temperature oxidation (HTO) process or a CVD process. The first oxide layer 110 and the second oxide layer 130 may be formed of the same material, and may be formed in the same method. In embodiments, the second oxide layer 130 may be formed using a CVD process. For example, a tetra-ethyl-ortho-silicate (TEOS) may be deposited at a temperature of about 650° C. to about 800° C. under a pressure of about 0.3 torr to about 0.5 torr. The second oxide layer 130 may be formed along the uppermost surface and sidewalls of the polysilicon layer pattern 120a and the sidewalls of the first oxide layer pattern 110a, and the exposed portion of the uppermost surface of the silicon substrate 100.

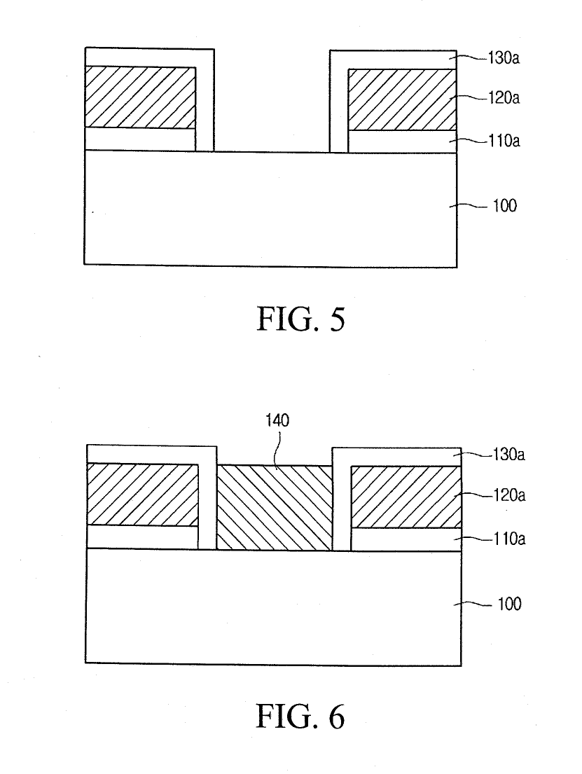

As illustrated in example FIG. 5, a portion of the second oxide layer 130 covering the top of the silicon substrate 100 may be selectively removed. A photoresist layer is formed on and/or over the silicon substrate 100 including the second oxide layer 130 and then patterned to form photoresist patterns exposing the portion of the second oxide layer 130 over the substrate 100. Thereafter, using the photoresist patterns as an etch mask, the second oxide layer 130 may be etched to expose a portion of the silicon substrate 100 between the polysilicon layer patterns. The second oxide layer pattern 130a is formed to cover the uppermost surface and sidewalls of the polysilicon layer pattern 120a and the sidewalls of the first oxide layer pattern 110a, and a portion of the uppermost surface of the silicon substrate 100 is again exposed.

As illustrated in example FIG. 6, a silicon layer is grown on and/or over the second oxide layer pattern 130a and the exposed silicon substrate 100, thereby forming a silicon epitaxial layer 140 on and/or over the exposed silicon substrate 100 and partially filling the trench. The silicon epitaxial layer 140 may be grown on and/or over the exposed silicon substrate 100 without being formed on and/or over the second oxide layer pattern 130a. The silicon epitaxial layer 140 may be formed to a thickness of about 1.0 μm to about 1.6 μm. The height of the silicon epitaxial layer 140 may be equal to or greater than the height of the polysilicon layer pattern 120a.

As illustrated by example FIG. 7, the second oxide layer pattern 130a formed on and/or over the uppermost surface of the polysilicon layer pattern 120a may be removed to expose the polysilicon layer pattern 120a. The second oxide layer pattern 130a may be removed using a chemical mechanical polishing (CMP) process or a wet etching process. During the process of polishing the second oxide layer pattern 130a, the uppermost surface of the silicon epitaxial layer 140 may also be polished and planarized so that it is coplanar with the uppermost surface of the polysilicon layer pattern 120a. Thus, the first oxide layer patterns 110a and the polysilicon layer patterns 120a are sequentially formed on and/or over the silicon substrate 100. The silicon epitaxial layer 140 is formed between the polysilicon layer patterns 120a, and the second oxide layer patterns 130b.

The polysilicon layer pattern 120a formed on and/or over the silicon substrate forms a trench-type gate in a MOSFET (metal-oxide-semiconductor field-effect transistor). The first oxide layer pattern 110a interposed between the polysilicon layer pattern 120a and the silicon substrate 100 serves as a gate insulating layer. The second oxide layer pattern 130a interposed between the polysilicon layer pattern 120a and the silicon epitaxial layer 140 also serves as a gate insulating layer. High-concentration ions may be implanted into the silicon epitaxial layer 140 formed in the moat region, so that a source region and a drain region are formed respectively on both sides of the trench-type gate.

The moat region including the polysilicon layer pattern 120a may be defined by device isolation layer patterns formed in the silicon epitaxial layer 140. The device isolation layer pattern includes a trench, which may be formed around the moat region in the silicon epitaxial layer 140, and an oxide layer that fills the trench.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An apparatus comprising:
a first oxide layer pattern formed over a silicon substrate;
a polysilicon layer pattern formed over the first oxide layer pattern;
a second oxide layer pattern formed on sidewalls of the polysilicon layer pattern and the silicon epitaxial layer;
a silicon epitaxial layer formed over the silicon substrate at sidewalls of the second oxide layer pattern;
a source/drain region formed in the silicon epitaxial layer.

2. The apparatus of claim 1, wherein the first oxide layer pattern and the second oxide layer pattern have the same thickness.

3. The apparatus of claim 1, wherein the first oxide layer and the second oxide layer are formed to a thickness in a range between approximately 200 Å to 300 Å.

4. The apparatus of claim 1, wherein the polysilicon layer is formed to a thickness of in a range between approximately 1.0 μm to 1.5 μm.

5. The apparatus of claim 1, wherein the silicon epitaxial layer is formed to a thickness in a range between approximately 1.0 μm to 1.6 μm.

6. The apparatus of claim 1, wherein the uppermost surface of the polysilicon layer is coplanar with the uppermost surface of the silicon epitaxial layer.

7. A method comprising:
forming a first oxide layer over a silicon substrate; and then
forming a polysilicon layer over the first oxide layer; and then
forming a polysilicon layer pattern and a first oxide layer pattern by etching the polysilicon layer and the first oxide layer to expose a portion of the silicon substrate; and then
forming a second oxide layer over the entire surface of the silicon substrate including the uppermost surface of the polysilicon layer pattern; and then
forming a second oxide layer pattern by etching the second oxide layer to expose a portion of the silicon substrate; and then
forming a silicon epitaxial layer by growing a silicon over the exposed silicon substrate; and then
removing a portion of the second oxide layer formed over the uppermost surface of the polysilicon layer pattern.

8. The method of claim 7, wherein forming the second oxide layer pattern comprises:
forming a photoresist pattern over the second oxide layer at the position of the polysilicon layer pattern; and then
etching the second oxide layer using the photoresist pattern as an etch mask.

9. The method of claim 7, wherein the second oxide layer pattern covers the uppermost surface and sidewalls of the polysilicon layer pattern.

10. The method of claim 7, wherein removing a portion of the second oxide layer is performed using at least one of a chemical mechanical polishing process and a wet etching process.

11. The method of claim 7, wherein the first oxide layer is formed using at least one of a thermal oxidation process or a chemical vapor deposition (CVD) process.

12. The method of claim 7, wherein the second oxide layer is formed using at least one of a thermal oxidation process or a chemical vapor deposition (CVD) process.

13. The method of claim 7, wherein the second oxide layer is formed by depositing a tetra-ethyl-ortho-silicate (TEOS) by chemical vapor deposition (CVD) at a temperature in a range between approximately 650° C. to 800° C.

14. The method of claim 7, wherein the second oxide layer is formed by depositing a tetra-ethyl-ortho-silicate (TEOS) by chemical vapor deposition (CVD) under a pressure in a range between approximately 0.3 torr to 0.5 torr.

15. The method of claim 7, wherein the first oxide layer pattern and the second oxide layer pattern have the same thickness.

16. The method of claim 7, wherein the first oxide layer and the second oxide layer are formed to a thickness in a range between approximately 200 Å to 300 Å.

17. The method of claim 7, wherein the polysilicon layer is formed to a thickness in a range between approximately 1.0 μm to 1.5 μm.

18. The method of claim 7, wherein the silicon epitaxial layer is formed to a thickness in a range between approximately 1.0 μm to 1.6 μm.

19. The method of claim 7, wherein forming the second oxide layer comprises forming the second oxide layer over the sidewalls of the first oxide layer pattern and the polysilicon layer pattern.

20. The method of claim 19, wherein forming the second oxide layer pattern comprises removing a portion of the second oxide layer formed over the uppermost surface of the semiconductor substrate to expose the portion of the uppermost surface of the semiconductor substrate.
